(19) United States
(12) Patent Application Publication
(10) Pub. No.: US 2019/0267938 A1
(43) Pub. Date: Aug. 29, 2019

(54) SYSTEM AND METHOD FOR COUPLING JUNCTION BOX TO SOLAR ROOF TILES

(71) Applicant: TESLA, INC., Palo Alto, CA (US)

(72) Inventors: Seth M. Winger, Palo Alto, CA (US); Bobby Yang, Dublin, CA (US); Kaleb A. Klauber, Oakland, CA (US)

(73) Assignee: TESLA, INC., Palo Alto, CA (US)

(21) Appl. No.: 15/905,551

(22) Filed: Feb. 26, 2018

(51) Int. Cl. H02S 40/34; H02S 20/25; H01L 31/048; H01L 31/02; H01L 31/05

(52) U.S. Cl. CPC H02S 40/34; H02S 20/25; H01L 31/0508; H01L 31/0201; H01L 31/048

(57) ABSTRACT

One embodiment can provide a photovoltaic roof module. The photovoltaic roof module can include one or more photovoltaic roof tiles. A respective photovoltaic roof tile can include a plurality of photovoltaic structures positioned between a front cover and a back cover. The photovoltaic roof module can further include a first junction box positioned on the back cover of a first photovoltaic roof tile, and the first junction box can include a physical enclosure and an attachment pad extended substantially vertically out of a surface of the physical enclosure. The attachment pad is configured to electrically access, via a through hole, photovoltaic structures within the first photovoltaic roof tile.

### BACKGROUND

### Field

This disclosure is generally related to photovoltaic (or “PV”) roof modules. More specifically, this disclosure is related to the coupling between a junction box and a PV roof module.

### Related Art

In residential and commercial solar energy installations, a building's roof typically is installed with photovoltaic (PV) modules, also called PV or solar panels, that can include a two-dimensional array (e.g., 6×12) of solar cells. A PV roof tile (or solar roof tile) can be a particular type of PV module offering weather protection for the home and a pleasing aesthetic appearance, while also functioning as a PV module to convert solar energy to electricity. The PV roof tile can be shaped like a conventional roof tile and can include one or more solar cells encapsulated between a front cover and a back cover, but typically enclose fewer solar cells than a conventional solar panel. The front and back covers can be fortified glass or other material that can protect the PV cells from the weather elements. Note that a typical roof tile may have a dimension of 15 in×8 in =120 in²=774 cm², and a typical solar cell may have a dimension of 6 in×6 in =36 in²=232 cm². Similar to a conventional PV panel, the PV roof tile can include an encapsulating layer, such as an organic polymer. A lamination process can seal the solar cells between the front and back covers.

To facilitate scalable production and easy installation of PV roof tiles, a group of tiles can be fabricated together as a single module. Like conventional PV panels, electrical interconnections among PV modules can be achieved via junction boxes.

### SUMMARY

One embodiment can provide a photovoltaic roof module. The photovoltaic roof module can include one or more photovoltaic roof tiles. A respective photovoltaic roof tile can include a plurality of photovoltaic structures positioned between a front cover and a back cover. The photovoltaic roof module can further include a first junction box positioned on the back cover of a first photovoltaic roof tile, and the first junction box can include a physical enclosure and an attachment pad extended substantially vertically out of a surface of the physical enclosure. The attachment pad is configured to electrically access, via a through hole, photovoltaic structures within the first photovoltaic roof tile.

In a variation on this embodiment, a respective photovoltaic structure can include a first edge busbar positioned near an edge of a first surface and a second edge busbar positioned near an opposite edge of a second surface, and the plurality of photovoltaic structures can be arranged in such a way that the first edge busbar of a first photovoltaic structure overlaps the second edge busbar of an adjacent photovoltaic structure, thereby forming a cascaded string.

In a further variation, the attachment pad of the first junction box can be electrically coupled to a first electrode of a first polarity of the cascaded string within the first photovoltaic tile.

In a further variation, the photovoltaic roof module can further include a second junction box positioned on the back cover of a second photovoltaic tile. An attachment pad of the second junction box can be electrically coupled to a second electrode of a second polarity of the cascaded string within the second photovoltaic tile.

In a further variation, the cascaded strings within the first and second photovoltaic tiles are electrically coupled to each other in parallel by a pair of metal tabs, and attachment pads of the first and second junction boxes are separately coupled to the pair of metal tabs.

In a variation on this embodiment, the attachment pad can include an extension post for extending out of the first junction box, a contact pad coupled to a first end of the extension post, and a wire coupler coupled to an opposite end of the extension post.

In a further variation, the contact pad is configured to be electrically and mechanically coupled to an electrode of the photovoltaic structures within the first photovoltaic roof tile.

In a further variation, the wire coupler is configured to be electrically and mechanically coupled to a lead wire, with a portion of the lead wire extending out of the physical enclosure, and the extended portion of the lead wire is inserted inside a weatherproof jacket.

In a further variation, the attachment pad can include Cu, and the contact pad and the wire coupler can be coated with a solder layer.

In a variation on this embodiment, the photovoltaic roof module can further include encapsulant positioned between the front and back covers and a gasket inserted into the through hole, thus preventing the encapsulant from overflowing into the through hole during lamination.

One embodiment can provide a method for fabricating a photovoltaic roof module. The method can include obtaining one or more cascaded strings of photovoltaic structures, laminating a cascaded string of photovoltaic structures between a front and back cover of a corresponding photovoltaic roof tile, and attaching a first junction box on the back cover of a first photovoltaic roof tile. The first junction box can include a physical enclosure and an attachment pad extended substantially vertically out of a surface of the physical enclosure, and the attachment pad can be configured to electrically access, via a through hole, photovoltaic structures laminated within the first photovoltaic roof tile.

One embodiment can provide a junction box of a photovoltaic roof tile module. The junction box can include a physical enclosure, an attachment pad extended substantially vertically out of a surface of the physical enclosure, and a lead wire electrically coupled to the attachment pad. A portion of the lead wire extends out of the physical enclosure, and the extended portion of the lead wire is inserted inside a weatherproof jacket.

A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” “smaller cell,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

“Busbar,” “bus line,” or “bus electrode” refer to elongated, electrically conductive (e.g., metallic) electrodes of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BRIEF DESCRIPTION OF THE FIGURES

FIG. 1 shows an exemplary configuration of PV roof tiles on a house.

FIG. 2 shows the perspective view of an exemplary photovoltaic roof tile, according to an embodiment.

FIG. 3 shows a cross-section of an exemplary photovoltaic roof tile, according to an embodiment.

FIG. 4A illustrates an exemplary configuration of a multi-tile module, according to one embodiment.

FIG. 4B illustrates a cross-section of an exemplary multi-tile module, according to one embodiment.

FIG. 5A illustrates a serial connection between three adjacent cascaded photovoltaic strips, according to one embodiment.

FIG. 5B illustrates the side view of the string of cascaded strips, according to one embodiment.

FIG. 5C illustrates an exemplary solar roof tile, according to one embodiment.

FIG. 6 shows the top view of an exemplary multi-tile module, according to one embodiment.

FIG. 7 shows the inter-tile coupling within an exemplary solar roof tile module, according to one embodiment.

FIG. 8A shows a detailed view of an exemplary strain-relief connector, according to one embodiment.

FIG. 8B illustrates the coupling between a strain-relief connector and the front side of a photovoltaic structure, according to one embodiment.

FIG. 8C illustrates the coupling between a strain-relief connector and the back side of a photovoltaic structure, according to one embodiment.

FIG. 9 illustrates a metal tab extruding out the back cover of a solar tile module.

FIG. 10A shows the bottom view of an exemplary tile module, according to one embodiment of the present invention.

FIG. 10B shows the cross-sectional view along cut plane B-B′, according to one embodiment.

FIG. 10C shows the top view of the through hole, according to one embodiment.

FIG. 10D shows an exemplary gasket, according to one embodiment.

FIG. 11A shows the side view of an exemplary junction box, according to one embodiment.

FIG. 11B shows the detailed view of an exemplary attachment pad, according to one embodiment.

FIG. 11C shows the exemplary coupling between the junction box and the tile module, according to one embodiment.

FIG. 12 shows the bottom view of an exemplary tile module, according to one embodiment of the present invention.

FIG. 13 shows an exemplary fabrication process of a photovoltaic roof module, according to an embodiment of the invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the disclosed system is not limited to the embodiments shown, but is to be accorded the widest scope consistent with the principles and features disclosed herein.

### Overview

Embodiments of the disclosed system solve the technical problem of coupling one or more junction boxes to a photovoltaic roof module. The junction boxes can play an important role in interconnecting photovoltaic (PV) modules, which can be a multi-tile module or a single tile module. In some embodiments, a photovoltaic roof tile can include a plurality of photovoltaic strips, which can be obtained by dividing conventional square or pseudo-square solar cells into multiple pieces, encapsulated between a front cover and a back cover. The photovoltaic strips within each photovoltaic roof tile can form a serially connected string. Multiple photovoltaic roof tiles can be electrically coupled in parallel and bonded by inter-tile spacers to form a multi-tile module. A pair of junction boxes can be attached to the back cover of each multi-tile module. Each junction box can facilitate electrical coupling between an external lead wire and an electrode of the string encapsulated inside the tile covers. Inter-module coupling can be achieved by coupling among the external lead wires, which can be performed during roof installation.

### Solar Roof Tiles and Tile Modules

In conventional PV panels, junction boxes have been used to house electrical components (e.g., wires, bypass diodes, etc.) that can be used to protect the panels and to enable interconnection among multiple panels. Similar to PV panels, the PV roof tiles or tile modules can also require protection and interconnections, thus also needing junction boxes. However, the unique design of the PV roof tiles or tile modules means that special considerations are needed when designing the junction box, including the connections between the junction box and the encapsulated photovoltaic string or strings.

A PV roof tile (or solar roof tile) is a type of PV module shaped like a roof tile and typically enclosing fewer solar cells than a conventional solar panel. Note that such PV roof tiles can function as both PV cells and roof tiles at the same time. PV roof tiles and modules are described in more detail in U.S. Provisional Patent Application No. 62/465,694, Attorney Docket Number P357-1PUS, entitled “SYSTEM AND METHOD FOR PACKAGING PHOTOVOLTAIC ROOF TILES” filed Mar. 1, 2017, which is incorporated herein by reference. In some embodiments, the system disclosed herein can be applied to PV roof tiles and/or other types of PV module.

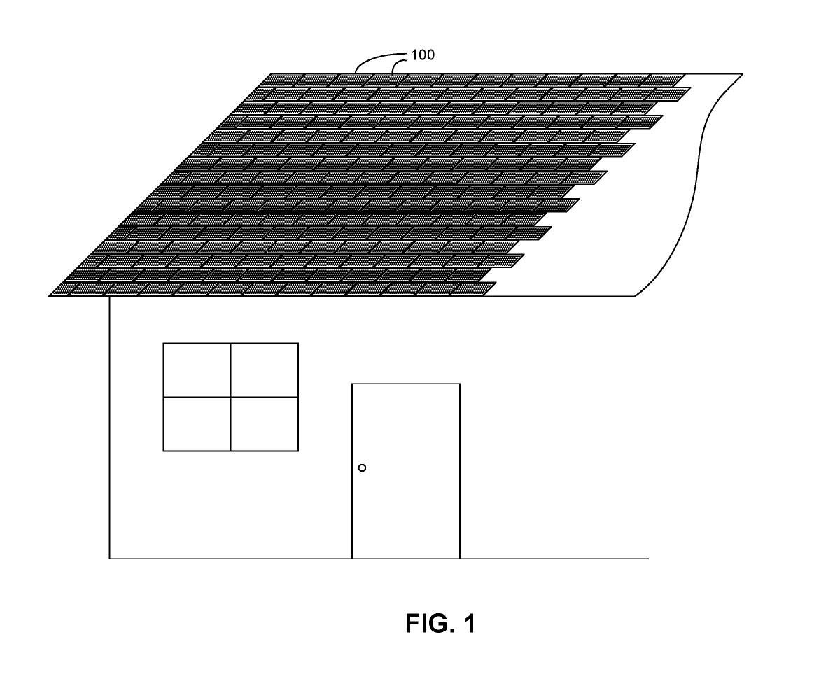

FIG. 1 shows an exemplary configuration of PV roof tiles on a house. PV roof tiles 100 can be installed on a house like conventional roof tiles or shingles. Particularly, a PV roof tile can be placed with other tiles in such a way as to prevent water from entering the building.

A PV roof tile can enclose multiple solar cells or PV structures, and a respective PV structure can include one or more electrodes such as busbars and finger lines. The PV structures within a PV roof tile can be electrically and optionally mechanically coupled to each other. For example, multiple PV structures can be electrically coupled together by a metallic tab, via their respective busbars, to create serial or parallel connections. Moreover, electrical connections can be made between two adjacent tiles, so that a number of PV roof tiles can jointly provide electrical power.

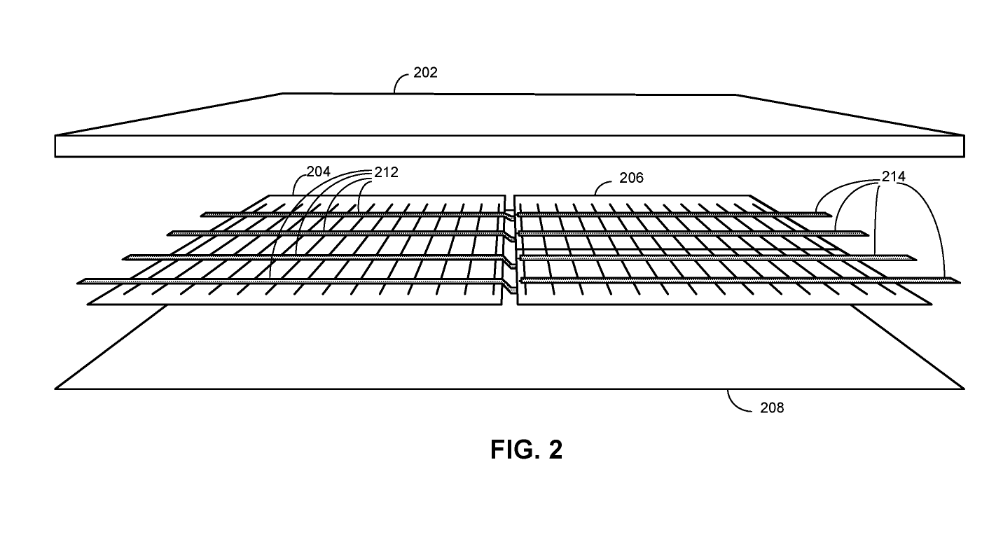

FIG. 2 shows the perspective view of an exemplary photovoltaic roof tile, according to an embodiment. Solar cells 204 and 206 can be hermetically sealed between top glass cover 202 and backsheet 208, which jointly can protect the solar cells from various weather elements. In the example shown in FIG. 2, metallic tabbing strips 212 can be in contact with the front-side electrodes of solar cell 204 and extend beyond the left edge of glass 202, thereby serving as contact electrodes of a first polarity of the PV roof tile. Tabbing strips 212 can also be in contact with the back side of solar cell 206, creating a serial connection between solar cell 204 and solar cell 206. On the other hand, tabbing strips 214 can be in contact with front-side electrodes of solar cell 206 and extend beyond the right edge of glass cover 202, serving as contact electrodes of a second polarity of the PV roof tile.

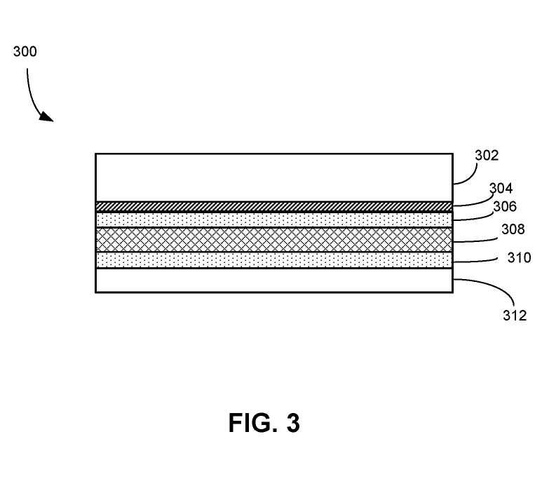

FIG. 3 shows a cross-section of an exemplary photovoltaic roof tile, according to an embodiment. Solar cell or array of solar cells 308 can be encapsulated between top glass cover 302 and back cover 312, which can be fortified glass or a regular PV backsheet. Top encapsulant layer 306, which can be based on a polymer, can be used to seal top glass cover 302 and solar cell or array of solar cells 308. Specifically, encapsulant layer 306 may include polyvinyl butyral (PVB), thermoplastic polyolefin (TPO), ethylene vinyl acetate (EVA), or N,N′-diphenyl-N,N′-bis(3-methylphenyl)-1,1′-diphenyl-4,4′-diamine (TPD). Similarly, lower encapsulant layer 310, which can be based on a similar material, can be used to seal array of solar cells 308 and back cover 312. A PV roof tile can also contain other optional layers, such as an optical filter or coating layer or a layer of nanoparticles for providing desired color appearances. In the example of FIG. 3, module or roof tile 300 also contains an optical filter layer 304.

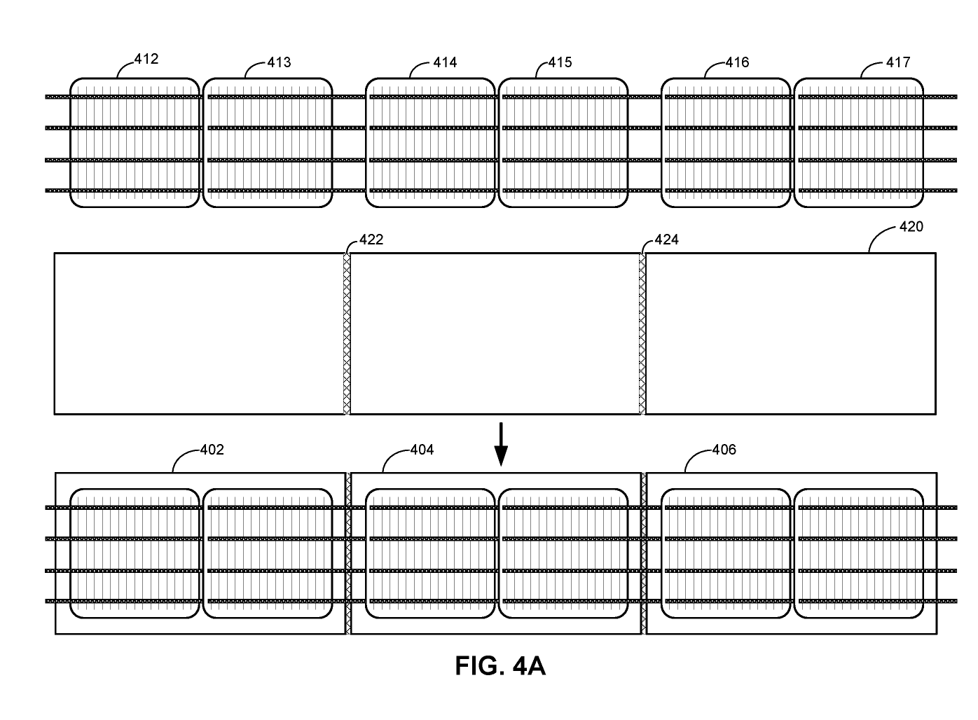

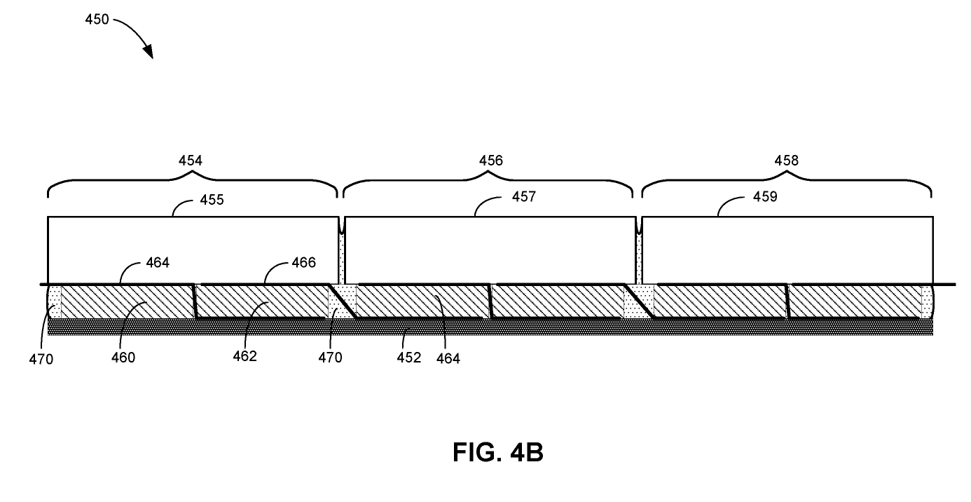

To facilitate more scalable production and easier installation, multiple photovoltaic roof tiles can be fabricated together, while the tiles are linked in a rigid or semi-rigid way. FIG. 4A illustrates an exemplary configuration of a multi-tile module, according to one embodiment. In this example, three PV roof tiles 402, 404, and 406 can be manufactured together. During fabrication, solar cells 412 and 413 (corresponding to tile 402), 414 and 415 (corresponding to tile 404), and 416 and 417 (corresponding to tile 406) can be laid out with tabbing strips interconnecting their corresponding busbars, forming a connection in series. Furthermore, these six solar cells can be laid out on a common backsheet. Subsequently, front-side glass cover 420 can be sealed onto these six PV cells.

It is possible to use a single piece of glass as glass cover 420. In one embodiment, grooves 422 and 424 can be made on glass cover 420, so that the appearance of three separate roof tiles can be achieved. It is also possible to use three separate pieces of glass to cover the six cells, which are laid out on a common backsheet. In this case, gaps 422 and 424 can be sealed with an encapsulant material, establishing a semi-rigid coupling between adjacent tiles. Prefabricating multiple tiles into a rigid or semi-rigid multi-tile module can significantly reduce the complexity in roof installation, because the tiles within the module have been connected with the tabbing strips. Note that the numbers of tiles included in each multi-tile module can be more or fewer than what is shown in FIG. 4A.

FIG. 4B illustrates a cross-section of an exemplary multi-tile module, according to one embodiment. In this example, multi-tile module 450 can include photovoltaic roof tiles 454, 456, and 458. These tiles can share common backsheet 452, and have three individual glass covers 455, 457, and 459, respectively. Each tile can encapsulate two solar cells. For example, tile 454 can include solar cells 460 and 462 encapsulated between backsheet 452 and glass cover 455. Tabbing strips can be used to provide electrical coupling within each tile and between adjacent tiles. For example, tabbing strip 464 can couple the front electrode of solar cell 460 to the back electrode of solar cell 462, creating a serial connection between these two cells. Similarly, tabbing strip 466 can couple the front electrode of cell 462 to the back electrode of cell 464, creating a serial connection between tile 454 and tile 456.

The gap between two adjacent PV tiles can be filled with encapsulant, protecting tabbing strips interconnecting the two adjacent tiles from the weather elements. For example, encapsulant 470 fills the gap between tiles 454 and 456, protecting tabbing strip 466 from weather elements. Furthermore, the three glass covers, backsheet 452, and the encapsulant together form a semi-rigid construction for multi-tile module 450. This semi-rigid construction can facilitate easier installation while providing a certain degree of flexibility among the tiles. In some embodiments, each PV roof tile can have its own front cover and back sheet, and adjacent PV roof tiles can be joined by a semi-rigid reinforcement spacer.

In addition to the examples shown in FIGS. 4A and 4B, a PV tile may include different forms of photovoltaic structures. For example, in order to reduce internal resistance, each square solar cell shown in FIG. 4A can be divided into multiple (e.g., three) smaller strips, each having edge busbars of different polarities on its two opposite edges. The edge busbars allow the strips to be cascaded one by one to form a serially connected string.

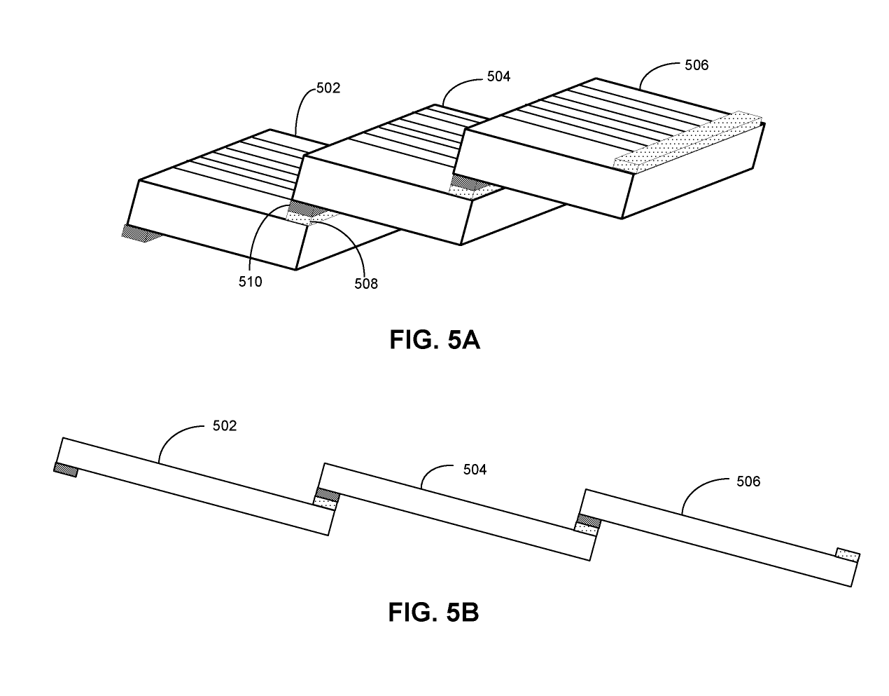

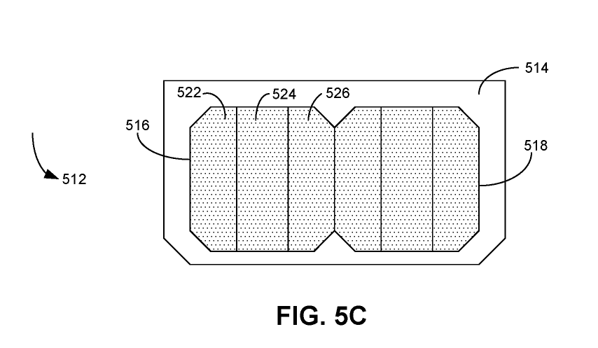

FIG. 5A illustrates a serial connection between three adjacent cascaded photovoltaic strips, according to one embodiment. In FIG. 5A, strips 502, 504, and 506 are stacked in such a way that strip 504 partially overlaps adjacent strip 506 to its right, and strip 502 to its left. The resulting string of strips forms a cascaded pattern similar to roof shingles. Strips 502 and 504 are electrically coupled in series via edge busbar 508 at the top surface of strip 502 and edge busbar 510 at the bottom surface of strip 504. Strips 502 and 504 can be arranged in such a way that bottom edge busbar 510 is above and in direct contact with top edge busbar 508. The coupling between strips 504 and 506 can be similar.

FIG. 5B illustrates the side view of the string of cascaded strips, according to one embodiment. In the example shown in FIGS. 5A and 5B, the strips can be segments of a six-inch square or pseudo-square solar cell, with each strip having a dimension of approximately two inches by six inches. To reduce shading, the overlapping between adjacent strips should be kept as small as possible. Therefore, in the example shown in FIGS. 5A and 5B, the single busbars (both at the top and the bottom surfaces) can be placed at or near the very edge of the strip. The same cascaded pattern can extend along multiple strips to form a serially connected string, and a number of strings can be coupled in series or parallel.

FIG. 5C illustrates an exemplary solar roof tile, according to one embodiment. A solar roof tile 512 includes top glass cover 514 and solar cells 516 and 518. The bottom cover (e.g., backsheet) of solar roof tile 512 is out of view in FIG. 5C. Solar cells 516 and 518 can be conventional square or pseudo-square solar cells, such as six-inch solar cells. In some embodiments, solar cells 516 and 518 can each be divided into three separate pieces of similar size. For example, solar cell 516 can include strips 522, 524, and 526. These strips can be arranged in such a way that adjacent strips are partially overlapped at the edges, similar to the ones shown in FIGS. 5A-5B. For simplicity of illustration, the electrode grids, including the finger lines and edge busbars, of the strips are not shown in FIG. 5C. In addition to the example shown in FIG. 5C, a solar roof tile can contain fewer or more cascaded strips, which can be of various shapes and size.

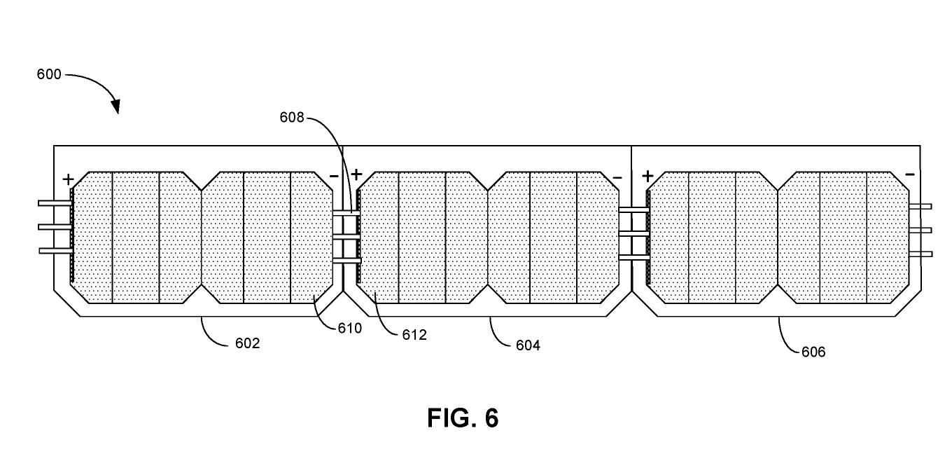

When multiple tiles are pre-assembled to form a multi-tile module, inter-tile electrical coupling needs to be established within the multi-tile module. One straightforward solution is to connect the tiles in series. FIG. 6 shows the top view of an exemplary multi-tile PV module, according to one embodiment. Multi-tile PV module 600 can include PV roof tiles 602, 604, and 606 arranged side by side. Each PV roof tile can include six cascaded strips encapsulated between the front and back covers. The cascaded strips within each PV roof tile form a serially connected string. Furthermore, metal tabs can be used to couple the strings enclosed in adjacent tiles in series by connecting the negative polarity of a string to the positive polarity of an adjacent string. For example, metal tab 608 can couple the edge busbar on the front side of strip 612 with the edge busbar on the back side of strip 610, creating a serial coupling between strips 610 and 612 and between the string within tile 602 and the string within tile 604. Although the example in FIG. 6 shows three metal tabs interconnecting the photovoltaic strips, other numbers of metal tabs can also be used. Furthermore, other coupling mechanisms, such as a single wide metallic tab overlapping the adjacent edge busbars of the adjacent tiles, can also be used to couple the tiles in series.

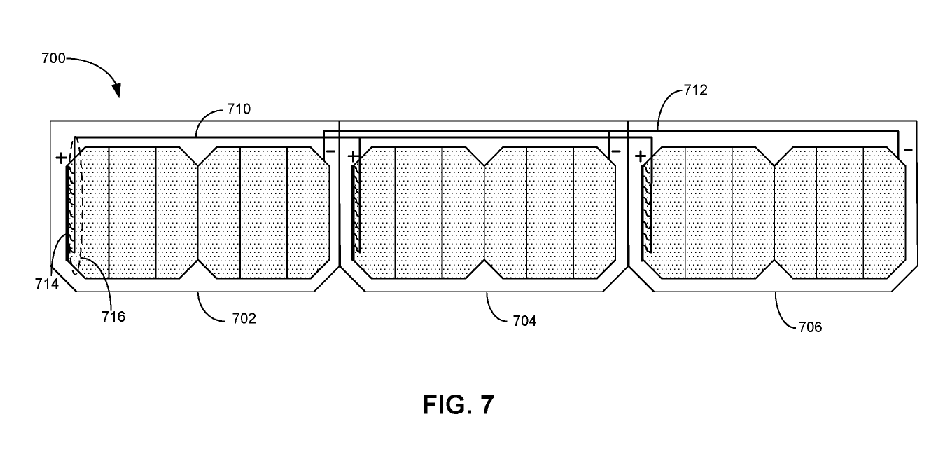

However, a multi-tile module with serially coupled PV tiles can have too high an output voltage and too low an output current. In some embodiments, the tiles within the multi-tile module are coupled to each other in parallel. FIG. 7 shows the inter-tile coupling within an exemplary multi-tile PV module, according to one embodiment. Multi-tile PV module 700 can include solar roof tiles 702, 704, and 706 arranged side by side. Solar roof tiles 702, 704, and 706 can be similar to solar roof tile 512 shown in FIG. 5C. Each solar roof tile can include six cascaded strips encapsulated between the front and back covers, meaning that busbars located at opposite edges of the cascaded string of strips have opposite polarities. For example, if the leftmost edge busbar of the strips in solar roof tile 702 has a positive polarity, then the rightmost edge busbar of the strips will have a negative polarity. Parallel connections can be established among the tiles by electrically coupling busbars having the same polarity.

In the example shown in FIG. 7, the solar roof tiles are arranged in such a way that their sun-facing sides have the same electrical polarity. As a result, the edge busbars of the same polarity will be on the same left or right edge. For example, the leftmost edge busbar of all solar roof tiles can have a positive polarity and the rightmost edge busbar of all solar roof tiles can have a negative polarity, or vice versa. In FIG. 7, the left edge busbars of all strips have a positive polarity (indicated by the “+” signs) and are located on the sun-facing (or front) surface of the strips, whereas the right edge busbars of all strips have a negative polarity (indicated by the “−” signs) and are located on the back surface. Depending on the design of the layer structure of the solar cell, the polarity and location of the edge busbars can be different from those shown in FIG. 7.

A parallel connection among the tiles can be formed by electrically coupling all leftmost busbars together via metal tab 710 and all rightmost busbars together via metal tab 712. Metal tabs 710 and 712 are also known as connection buses and typically can be used for interconnecting individual solar cells or strings. A metal tab can be stamped, cut, or otherwise formed from conductive material, such as copper. Copper is a highly conductive and relatively low-cost connector material. However, other conductive materials such as silver, gold, or aluminum can be used. In particular, silver or gold can be used as a coating material to prevent oxidation of copper or aluminum. In some embodiments, alloys that have been heat-treated to have super-elastic properties can be used for all or part of the metal tab. Suitable alloys may include, for example, copper-zinc-aluminum (CuZnAl), copper-aluminum-nickel (CuAlNi), or copper-aluminum-beryllium (CuAlBe). In addition, the material of the metal tabs disclosed herein can be manipulated in whole or in part to alter mechanical properties. For example, all or part of metal tabs 710 and 712 can be forged (e.g., to increase strength), annealed (e.g., to increase ductility), and/or tempered (e.g. to increase surface hardness).

The coupling between a metal tab and a busbar can be facilitated by a specially designed strain-relief connector. In FIG. 7, strain-relief connector 716 can be used to couple busbar 714 and metal tab 710. Such strain-relief connectors are needed due to the mismatch of the thermal expansion coefficients between metal (e.g., Cu) and silicon. More particularly, metal tends to expand or contract more than Si-based photovoltaic strips when the solar roof tile is heated or cooled, thus initiating shear forces at bonded joints between the metal tabs and the photovoltaic strips. Specially designed strain-relief connectors can help alleviate destructive thermal expansion and contraction effects in the solar roof tiles.

As shown in FIG. 7, the metal tabs (e.g., tabs 710 and 712) may cross paths with strain-relief connectors of opposite polarities. To prevent an electrical short of the photovoltaic strips, portions of the metal tabs and/or strain-relief connectors can be coated with an insulation film or wrapped with a sheet of insulation material.

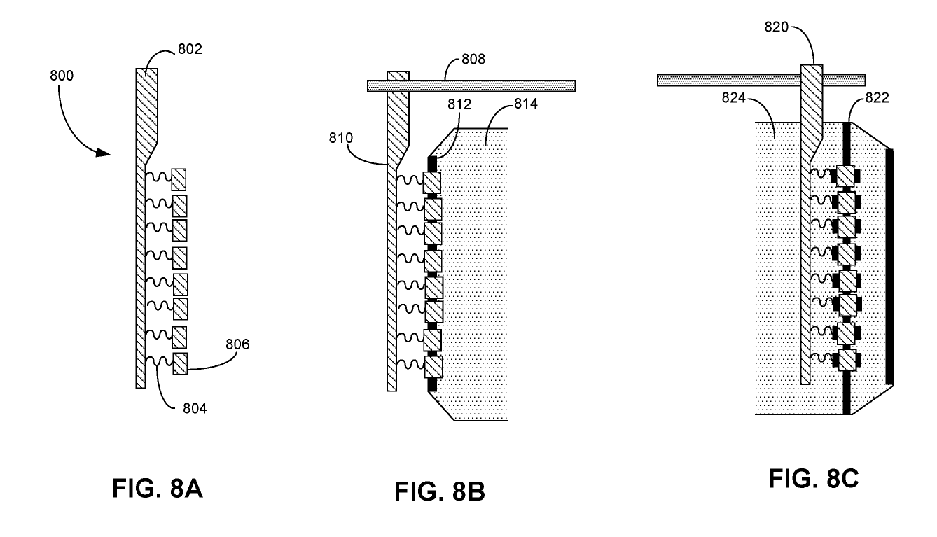

FIG. 8A shows a detailed view of an exemplary strain-relief connector, according to one embodiment. In FIG. 8A, strain-relief connector 800 can include elongated connection member 802, a number of curved metal wires (e.g., curved metal wire 804), and a number of connection pads (e.g., connection pad 806). Elongated connection member 802 can extend along a direction substantially parallel to the to-be-coupled busbar of a photovoltaic structure. The curved metal wires can extend laterally from elongated connection member 802 in a non-linear manner (i.e., having non-linear geometry). Non-linear geometry can include paths that centrally follow a curved wire (e.g., a path that extends along a series of centermost points located between outermost edges) or along any face or edge of the wire. A curved wire having non-linear geometry can have, but does not require, symmetry along the path of elongation. For example, one edge, or portion of an edge, of a curved wire can be straight and an opposite edge can include one or more curves, cuts, or extensions. Curved wires having non-linear geometry can include straight portions before, after, and/or between non-linear portions. Non-linear geometry can include propagating paths that extend laterally along a first axis (e.g., X axis) while alternating direction in negative and positive directions of one or more other axes (e.g., Y axis and/or Z axis) that are perpendicular to the first axis, in a repetitive manner, such as a sine wave or helix. While the curved wires disclosed herein use curved profiles, non-linear geometry can be constructed from a series of straight lines; for example, propagating shapes, such as square or sawtooth waves, can form non-linear geometry. These curved wires can relieve the strain generated due to the mismatch of thermal expansion coefficients between the metal connector and the Si-based photovoltaic structure.

In some embodiments, each curved metal wire can be attached to a connection pad. For example, curved metal wire 804 can be attached to connection pad 806. In alternative embodiments, more than one (e.g., two or three) curved wires can be attached to a connection pad. The elongated connection member 802, the curved wires, and the connection pads can be formed (e.g., stamped or cut) from a single piece of material, or they can be attached to each other by any suitable electrical connection, such as by soldering, welding, or bonding.

FIG. 8B illustrates the coupling between a strain-relief connector and the front side of a photovoltaic structure, according to one embodiment. More specifically, strain-relief connector 810 is coupled to edge busbar 812 of photovoltaic structure 814 by overlapping its connection pads with the front side of edge busbar 812. FIG. 8B also shows the coupling between strain-relief connector 810 and metal tab 808. More specifically, strain-relief connector 810 can be in direct contact with metal tab 808, and the metal-to-metal contact can create an electrical coupling. In some embodiments, electrically conductive adhesive (ECA) can be applied to electrically and mechanically couple strain-relief connector 810 and metal tab 808. Metal tab 808 can be similar to metal tab 710 or 712 shown in FIG. 7 and can be used to couple one solar tile to an adjacent solar tile.

FIG. 8C illustrates the coupling between a strain-relief connector and the back side of a photovoltaic structure, according to one embodiment. More specifically, strain-relief connector 820 can be coupled to busbar 822 of photovoltaic structure 824 by overlapping its connection pads with contact pads belonging to busbar 822. ECA can also be applied to create an electrical and mechanical bond. Note that, unlike the front side, the back side of a photovoltaic structure can include additional busbars because there is no need to worry about shading on the back side. To facilitate better adhesion and electrical access, the additional busbars on the back side of the PV structure can also include widened regions, known as contact pads. Detailed descriptions of such contact pads can be found in U.S. patent application Ser. No. 14/831,767, Attorney Docket Number P142-1NUS, filed Aug. 20, 2015, and entitled “Photovoltaic Electrode Design with Contact Pads for Cascaded Application,” the disclosure of which is incorporated herein by reference in its entirety.

### Inter-Module Connections

Because the photovoltaic structures and the inner- and inter-tile electrical interconnects are encapsulated between the front and back covers of the solar tiles, external lead wires are needed to facilitate inter-module electrical interconnections. In conventional PV panels, external lead wires may access the solar cell electrodes via pre-cut slots at the back side of the PV panel. For example, bussing ribbons may reach, through pre-cut slots on the PV panel backsheet, a junction box attached to the back side of the PV panel. Similar approaches may be used in solar roof tiles or tile modules. For example, a pre-cut hole or slot can be created at the back side of the solar roof tile or tile module. After lamination, the metal tabs (e.g., metal tabs 710 and 712 shown in FIG. 7) can be brought out through the pre-cut hole.

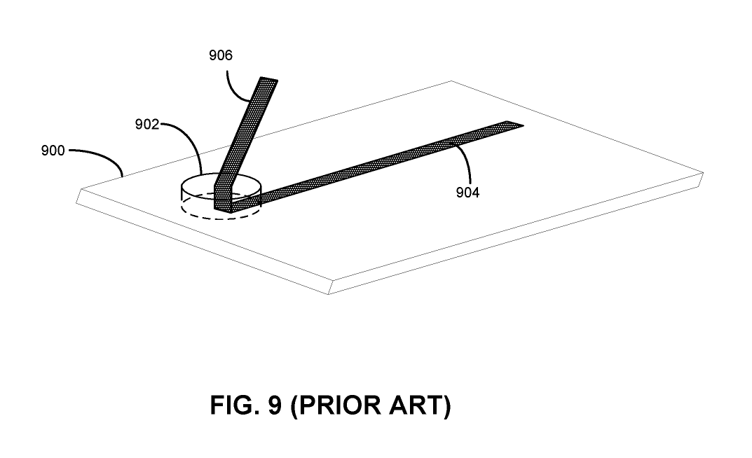

FIG. 9 illustrates a metal tab extruding out the back cover of a solar tile module. In FIG. 9, back cover 900 can include a pre-cut through hole 902. For illustration purposes, back cover 900 is shown as transparent in FIG. 9. Metal tab 904, which is coupled to an edge busbar (or a non-edge busbar on the backside) of a cascaded string (not shown in FIG. 9), can be encapsulated between back cover 900 and a front cover (not shown in FIG. 9) along the cascaded string. After lamination, metal tab 904 can be pulled out of the laminated tile or tile module via pre-cut through hole 902. Extruded portion 906 of metal tab 904 can then be sent to the junction box (e.g., soldered to an electrode inside the junction box), which can include protection circuitry and facilitate inter-module electrical coupling.

However, pulling a portion of metal tab 904 out of pre-cut through hole 902 can requiring bending, folding, and sometimes trimming of metal tab 904. These operations, including the pulling operation, typically are manual processes, which can be cumbersome and time-consuming. On the other hand, high throughput can be critical to the fabrication of solar roof tiles or tile modules. It can be preferable to have a system or process that can attach a junction box to a tile or tile module within a few seconds (e.g., two or three seconds). Manual operations certainly cannot meet such a challenge.

To solve this problem, in some embodiments, a unique junction box can be provided which can enable automated coupling between the junction box and encapsulated photovoltaic strings. Similar to the example shown in FIG. 9, one or more through holes can be created on the back cover of a tile module to enable coupling between the junction box and the encapsulated photovoltaic strings.

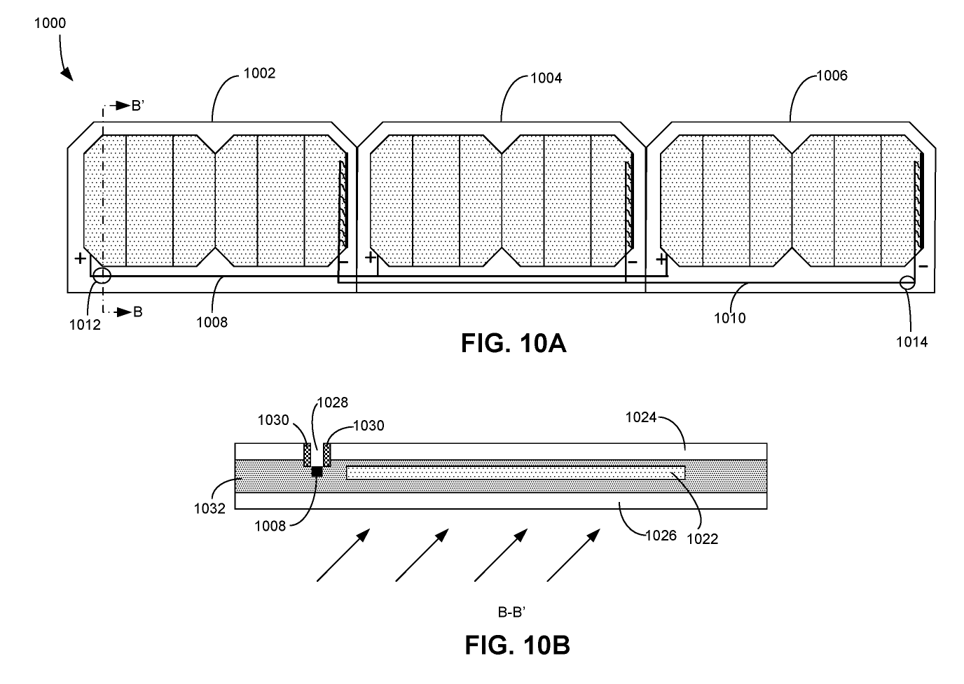

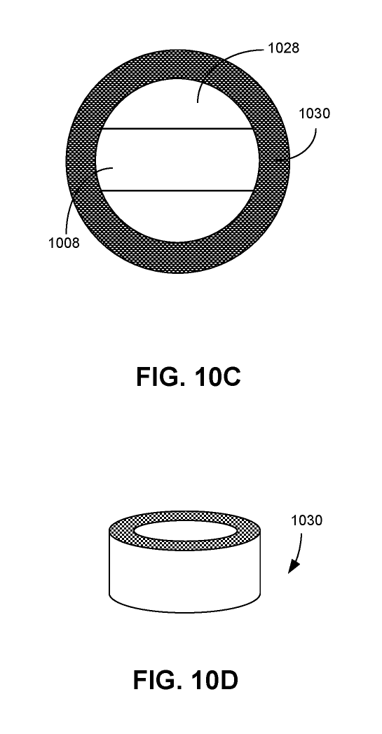

FIG. 10A shows the bottom view of an exemplary tile module, according to one embodiment of the present invention. For illustration purposes, the bottom covers of the solar roof tiles are shown as transparent. In practice, the bottom covers typically are non-transparent, such as back sheets or glass with dark colored coatings. Multi-tile module 1000 includes PV tiles 1002, 1004, and 1006, and each tile can include a number (e.g., six) of cascaded photovoltaic strips. Metal tabs 1008 and 1010 couple the PV tiles in parallel, such that edge busbars of positive polarity are coupled to metal tab 1008 and edge busbars of negative polarity are coupled to metal tab 1010. If one views multi-tile module 1000 as a battery, metal tabs 1008 and 1010 can provide the positive and negative outputs, respectively, of the battery. Hence, by allowing contacts between external lead wires and metal tabs 1008 and 1010, one can output power from multi-tile module 1000 via the external wires. In some embodiments, through holes can be created on the back cover of multi-tile module 1000 to enable electrical contacts between a pair of external lead wires and metal tabs 1008 and 1010.

In FIG. 10A, through holes 1012 and 1014 can be created on the back cover of tiles 1002 and 1006, respectively. More specifically, through hole 1012 can be positioned above a portion of metal tab 1008, and through hole 1014 can be created beneath a portion of metal tab 1010. To prevent encapsulant from flowing into the through holes during lamination, in some embodiments, an encapsulant-blocking ring can be placed around a through hole at the inner surface of the back cover. The encapsulant-blocking ring can be made of a material that can withstand the lamination temperature, such as polyethylene or other similar materials. The thickness of the ring can be between a few hundred microns to a few millimeters. Because the surface of the encapsulant-blocking ring is taller than the surface of the through hole, during lamination, the flow of encapsulant can be stopped by the encapsulant-blocking ring. As a result, the encapsulant will not contaminate metal tabs 1008 and 1010. Alternatively, a gasket (e.g., a rubber or PTFE O-ring) can be inserted into each through hole prior to the lamination process to prevent encapsulant from flowing into the through holes during lamination.

FIG. 10B shows the cross-sectional view along cut plane B-B′, according to one embodiment. The arrows show the direction of the sunlight. In FIG. 10B, photovoltaic strip 1022 is positioned between back cover 1024 and front cover 1026, and metal tab 1008 is positioned adjacent to the front surface of photovoltaic strip 1022. Metal tab 1008 is coupled to a busbar located on the front surface of photovoltaic strip 1022. Through hole 1028 is created on back cover 1024, directly above a portion of metal tab 1008. Gasket 1030 is inserted inside through hole 1028 to create a passage to metal tab 1008. Encapsulant 1032 can fill the remaining void between front cover 1026 and back cover 1024. As one can see from FIG. 10B, a clear passage to metal tab 1008 can be formed by through hole 1028 and gasket 1030. By carefully designing the size and shape of gasket 1030 to match those of through hole 1028, one can prevent contamination of metal tab 1008 by encapsulant 1032 during lamination.

FIG. 10C shows the top view of the through hole, according to one embodiment. In FIG. 10C, a portion of metal tab 1008 is exposed via through hole 1028. FIG. 10D shows an exemplary gasket, according to one embodiment. In some embodiments, gasket 1030 can be similar to an O-ring.

In some embodiments, a specially designed junction box can be used to facilitate electrical access to photovoltaic strings encapsulated with the tile module. More specifically, the junction box can include an electrical coupling mechanism configured to extend upwardly, from the bottom surface of the junction box, into the through hole, making contact with the exposed portion of the metal tab (e.g., metal tab 1008 or 1010. The electrical coupling mechanism can be in the form of an attachment pad that includes a flat (sometimes round) piece for making contact with the exposed portion of the metal tab and an extension post extending beyond the surface of the back cover. The busbar of the photovoltaic strip, the metal tab, and the attachment pad together can create a conductive path from one side of the photovoltaic strip to the exterior of the tile. In some embodiments, the extension post of the attachment pad can be enclosed inside a junction box, which can provide electrical insulation and weather protection for the attachment pad.

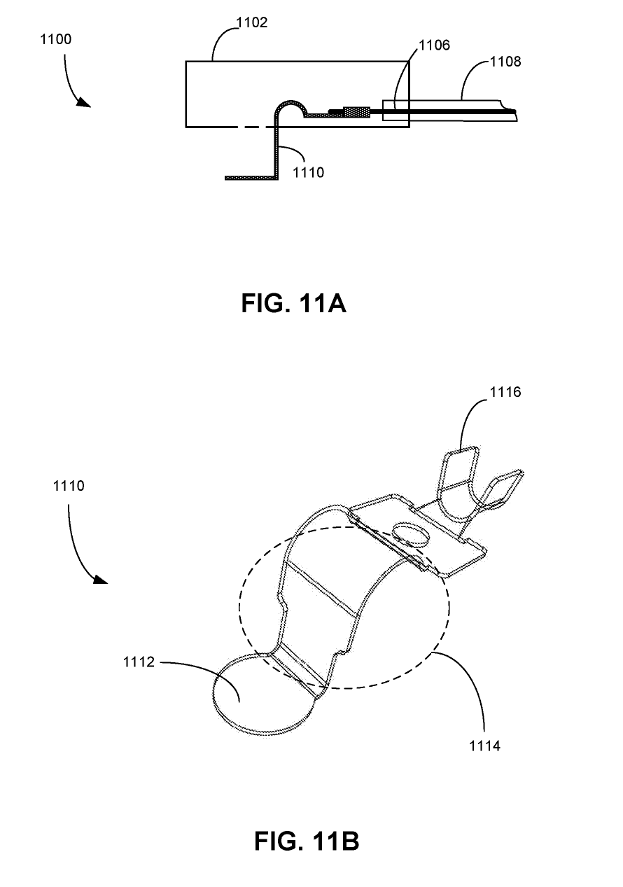

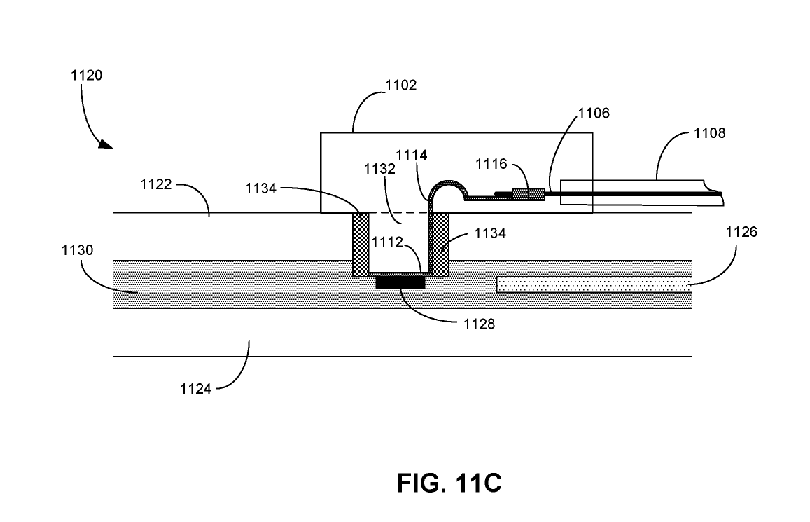

FIG. 11A shows the side view of an exemplary junction box, according to one embodiment. In FIG. 11A, junction box 1100 can include physical enclosure 1102, specially designed attachment pad 1110, and lead wire 1106. Junction box 1100 can also include other conventional electrical components, such as bypass diodes, that are not shown in the drawing.

Physical enclosure 1102 can be a weatherproof container that houses the various electrical components (e.g., attachment pad 1110, lead wire 1106, bypass diodes, etc.), protecting the electrical circuitry from weather elements. In some embodiments, physical enclosure 1102 can include an opening on its surface facing the tile module to allow attachment pad 1110 to extend out of physical enclosure 1102 in a substantial vertical manner. Alternatively, a trap- or sliding-door can be created to allow attachment pad 1110 to extend out of physical enclosure 1102. Attachment pad 1110 can be made of a low-resistant material (e.g., a metallic material) and can extend out of physical enclosure 1102. In some embodiments, attachment pad 1110 can be inserted into a through hole located on the back cover of a tile module, making direct contact with a metallic electrode (e.g., metal tab 1008 or 1010 shown in FIG. 10) encapsulated within the tile module.

Lead wire 1106 can include a portion within junction box 1100 for coupling to attachment pad 1110 and a portion extending out of junction box 1100 for coupling to lead wires of other tile modules. In some embodiments, the inside portion of lead wire 1106 can include a bare copper wire, making a metal-to-metal contact with attachment pad 1110. The outside portion of lead wire 1106 can be inserted into weatherproof jacket 1108.

FIG. 11B shows the detailed view of an exemplary attachment pad, according to one embodiment. Attachment pad 1110 can include a flat piece (or a contact pad) 1112, extension post 1114, and wire coupler 1116. Flat piece or contact pad 1112 can have various shapes, such as circular. When inserted into the through hole on the back cover of a tile module, contact pad 1112 can be in direct contact with the exposed portion of a metal tab that is electrically coupled to the edge busbar of the photovoltaic string. Note that, if a gasket has been placed inside the through hole, contact pad 1112 can be inserted into the gasket. In some embodiment, electrically conductive adhesive (ECA) can be applied to bond contact pad 1112 with the metal tab. Alternatively, solder can also be used to bond contact pad 1112 with the metal tab. Note that, when the tile module is in operation, contact pad 1112 is located on the back side of the tile module; hence, there is no need for a masking layer on the contact pad, making soldering a suitable option for bonding. In some embodiments, contact pad 1112 can be pre-coated with a layer of solder (e.g., Pb- or Sn-based solder, including Sn₆₂Pb₃₆Ag₂). After being inserted into the through hole, heat can be applied (e.g., by using a solder gun) locally to melt the solder, thus bonding contact pad 1112 to the metal strip inside the tile module.

Extension post 1114 can be designed in such a way that its length is at least equal to or greater than the thickness of the back cover. In some embodiments, the back cover of a tile module can include glass having a thickness of around 2.5 mm, and extension post 1114 can be slightly longer, extending out of the physical enclosure for about 2.5 mm. Hence, when extended vertically from the junction box, extension post 1114 can reach beyond the back cover, bringing contact pad 1112 into contact with an electrode of the photovoltaic string (e.g., a metal tab coupled to an edge busbar or an edge busbar itself). In some embodiments, extension post 1114 can include a curved neck portion as shown in FIG. 11B. Such a design can allow adjustment to be made to the extended length of extension past 1114. Wire coupler 1116 is positioned at the other end of extension post 1114, opposite to contact pad 1112. Wire coupler 1116 can be configured to couple to a lead wire. In some embodiments, wire coupler 1116 can be shaped like a half cylindrical surface. Wire coupler 1116 can also be pre-coated with a solder layer to facilitate coupling between wire coupler 1116 and the lead wire.

Attachment pad 1110 can be made of low-resistant metallic materials, such as Cu. In some embodiments, the three different components within attachment pad 1110 can be formed from a single piece of metal. Alternatively, they can be attached to each other by any suitable electrical connection, such as by soldering, welding, or bonding.

FIG. 11C shows the exemplary coupling between the junction box and the tile module, according to one embodiment. More specifically, FIG. 11C shows the amplified view of a PV tile module at a location near the junction box. Tile module 1120 can include back cover 1122, front cover 1124, and photovoltaic strip 1126 encapsulated between back cover 1122 and front cover 1124. Metal tab 1128 is in contact with a busbar (e.g., an edge busbar) on photovoltaic strip 1126 and can be used to electrically couple photovoltaic strip 1126 with photovoltaic strips encapsulated in adjacent solar roof tiles. Through hole 1132 can be formed within back cover 1122 at a location directly above a portion of metal tab 1128. The location of through hole 1132 can be determined based on locations and/or sizes of other components of the tile module, such as the junction box, the inter-module spacer, etc. Gasket 1134 can be inserted into through hole 1132, preventing encapsulant 1130 from overflowing into through hole 1132 during lamination. As one can see in FIG. 11C, the rim of gasket 1134 is slightly over the inner surface of back cover 1122, thus effectively preventing the overflow of encapsulant 1130. Encapsulant 1130 can fill the remaining empty space between back cover 1122 and front cover 1124.

Physical enclosure 1102 of the junction box can be placed on back cover 1122, directly above through hole 1132. Because physical enclosure 1102 is weatherproof, when placed on top of through hole 1132, it can protect components exposed by through hole 1132 (e.g., metal tab 1128) from exposure to weather factors. An attachment pad can be inserted through gasket 1134, resulting in contact pad 1132 being in direct physical contact with metal tab 1128. In some embodiments, to ensure low-resistance contact, metal tab 1128 can include a widened section that is in contact with contact pad 1112. Extension post 1114 of the attachment pad extends out of through hole 1132 into physical enclosure 1102. Inside enclosure 1102, lead wire 1106 can be coupled to wire coupler 1116 of the attachment pad. In some embodiments, lead wire 1106 can include bare copper wire. The coupling can include a metal-to-metal contact. Before exiting junction box enclosure 1102, lead wire 1106 can be inserted into weatherproof jacket 1108. The length of external portion of lead wire 1106 can be determined based on the size of the tile module. It is desirable for the lead wire to be long enough to be able to couple to lead wires from adjacent tile modules.

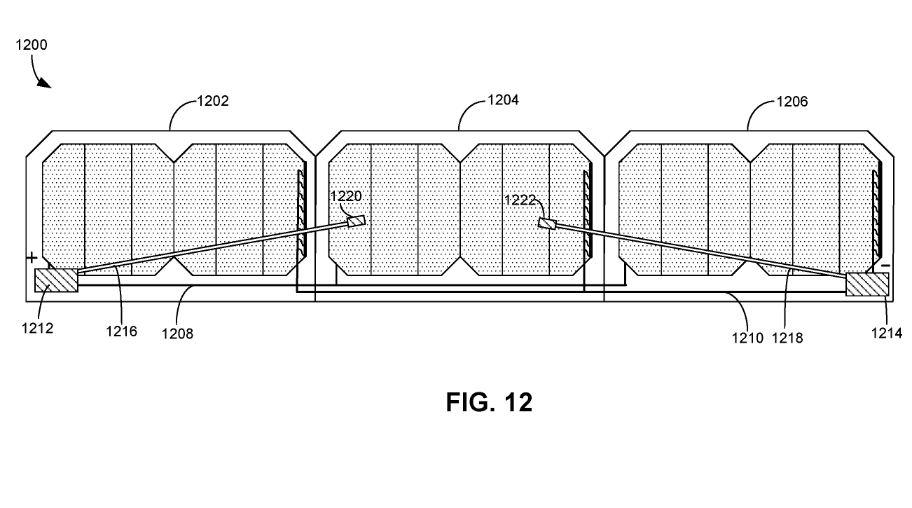

FIG. 12 shows the bottom view of an exemplary tile module, according to one embodiment of the present invention. Multi-tile module 1200 can include three PV tiles 1202, 1204, and 1206. In some embodiments, PV tiles 1202, 1204, and 1206 can be coupled in parallel via metal tabs 1208 and 1210. For example, metal tab 1208 can be coupled to positive-polarity busbars of all PV tiles within the module, whereas metal tab 1210 can be coupled to negative-polarity busbars of all PV tiles. Multi-tile module 1200 can also include junction boxes 1212 and 1214, both positioned on the back side of multi-tile module 1200. Similar to junction box 1100 shown in FIG. 11A, junction boxes 1212 and 1214 facilitate electrical coupling between weatherproof lead wires and metal tabs that couple the PV roof tiles. For example, junction box 1212 facilitates electrical coupling between weatherproof lead wire 1216 and metal tab 1208. Similarly, junction box 1214 facilitates electrical coupling between weatherproof lead wire 1218 and metal tab 1210. Therefore, weatherproof lead wires 1216 and 1218 are electrically coupled to the positive and negative polarities, respectively, of all PV tiles. Each weatherproof lead wire can also include a cable coupler, also weatherproof, for coupling to a lead wire of another tile module. Lead wire 1216 includes a cable coupler 1220, and lead wire 1218 includes a cable coupler 1222. During roof installation, depending on the layout and electrical design of the roof, an installer can interconnect individual multi-tile modules using the weatherproof lead wires. Additional bussing cables may also be used to facilitate inter-module electrical couplings.

The unique design of the junction boxes facilitates easy electrical access to a photovoltaic structure or string encapsulated inside the PV tile modules, thus enabling robust design of module interconnections. In the examples shown in FIGS. 7 and 12, the multiple PV roof tiles within a multi-tile module are arranged horizontally. In practice, it is also possible to arrange the multiple PV tiles within a module vertically. Regardless of the shape and size of a tile module, the specially designed junction box can be used for inter-module electrical connections. In some embodiments, a tile module may contain only a single PV roof tile, and the junction boxes attached to the back cover of the tile module can be configured to electrically access the edge busbars of the encapsulated photovoltaic string in a similar way. For example, the attachment pad may couple directly to an edge busbar (e.g., the edge busbar on the back side of the string), or it may couple to an edge busbar (e.g., the edge busbar on the front side of the string) via a strain-relief connector. The single-tile module can provide additional layout flexibility and can be combined with multi-tile modules when forming a roof.

### Module Fabrication

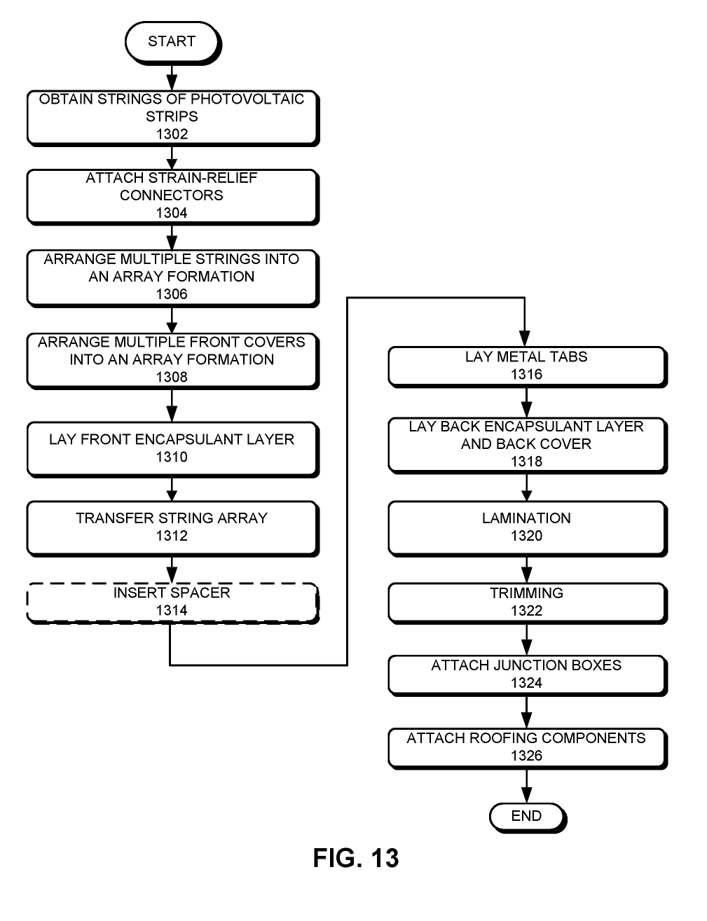

FIG. 13 shows an exemplary fabrication process of a photovoltaic roof module, according to an embodiment of the invention. During fabrication, one or more strings of photovoltaic strips can be obtained (operation 1302). More specifically, photovoltaic strips can be obtained by dividing a standard square or pseudo-square solar cell into multiple pieces, and a string of strips can be formed by cascading multiple strips at the edges. The cascading forms a serial connection among the strips. Detailed descriptions about the formation of a cascaded string of photovoltaic strips can be found in U.S. patent application Ser. No. 14/826,129, Attorney Docket No. P103-3NUS, entitled “PHOTOVOLTAIC STRUCTURE CLEAVING SYSTEM,” filed Aug. 13, 2015; U.S. patent application Ser. No. 14/866,776, Attorney Docket No. P103-4NUS, entitled “SYSTEMS AND METHODS FOR CASCADING PHOTOVOLTAIC STRUCTURES,” filed Sep. 25, 2015; U.S. patent application Ser. No. 14/804,306, Attorney Docket No. P103-5NUS, entitled “SYSTEMS AND METHODS FOR SCRIBING PHOTOVOLTAIC STRUCTURES,” filed Jul. 20, 2015; U.S. patent application Ser. No. 14/866,806, Attorney Docket No. P103-6NUS, entitled “METHODS AND SYSTEMS FOR PRECISION APPLICATION OF CONDUCTIVE ADHESIVE PASTE ON PHOTOVOLTAIC STRUCTURES,” filed Sep. 25, 2015; and U.S. patent application Ser. No. 14/866,817, Attorney Docket No. P103-7NUS, entitled “SYSTEMS AND METHODS FOR TARGETED ANNEALING OF PHOTOVOLTAIC STRUCTURES,” filed Sep. 25, 2015; the disclosures of which are incorporated herein by reference in their entirety.

In some embodiments, each individual solar roof tile may include one string, and each string can include six cascaded strips. The outputs of a string are busbars located at opposite sides and edges of the string. Additional busbars may also be added to the string to satisfy the spatial constraints imposed onto the junction boxes. An additional busbar can run alongside an edge busbar but is away from the edge. Subsequent to the formation of a string, strain-relief connectors can be attached to appropriate busbars (e.g., an edge busbar or an additional busbar away from the edge) (operation 1304). Various electrical coupling methods can be used to attach the strain-relief connectors to the busbars, including but not limited to: soldering, welding, or bonding with electrically conductive adhesive (ECA). In some embodiments, the strain-relief connectors may be coated with a masking layer (e.g., a layer of acrylic paint), and to protect the integrity of the masking layer, ECA is used to bond the strain-relief connectors to the busbars. Because the busbars can reside on opposite sides of the photovoltaic string, attaching the strain-relief connectors to the busbars may require flipping over the string.

Multiple strings along with their strain-relief connectors can then be arranged into a matrix or array formation that corresponds to the formation of a tile module (operation 1306). For example, to obtain a multi-tile module having three side-by-side tiles (e.g., as shown in FIG. 7), three strings can be arranged along a straight line, and the distance between adjacent strings can be determined based on the size of the tiles and the gap between the tiles. Similarly, front covers of multiple solar roof tiles can be arranged into a formation that corresponds to the formation of the tile module (operation 1308), and front encapsulant layer can be laid on the covers (operation 1310).

In some embodiments, three separate covers, each corresponding to a respective tile, can be used for the tile module. Alternatively, a single piece of glass cover can be used for all three tiles, and grooves can be etched on the single glass cover to create the appearance of three individual roof tiles. In a further embodiment, the front cover of the tile module may include three separate pieces of glass, whereas the back cover of the tile module may include a single continuous backsheet. Similarly, the encapsulant layer can be three separate pieces or a continuous piece of material.

The array of strings can then be transferred and placed on top of the front encapsulation layer and covers (operation 1312), and optionally, spacers can be inserted between adjacent tiles (operation 1314). Note that the spacer may not be used if both the front and back covers are made of a single piece of glass.

Metal tabs (e.g., metal tabs 710 and 712 shown in FIG. 7) can then be laid out, directly contacting the strain-relief connectors (operation 1316). In some embodiments, metal tabs can be laid out in such a way that the multiple strings can be coupled to each other in parallel. ECA can also be used to electrically and mechanically couple the metal tabs and strain-relief connectors. Subsequently, a back encapsulant layer and a back cover (or multiple back covers) are laid on top of the array of strings (operation 1318). In some embodiments, the back encapsulant layer and the back cover of the tile module can include through holes, and gaskets can be inserted inside the through holes. The locations of these through holes correspond to the locations of subsequently attached junction boxes. A lamination process can then be performed to encapsulate the strings, the strain-relief connectors, and the metal tabs between the front and back covers (operation 1320). The gaskets inserted into the through holes create a clear path to an exposed portion of the metal tabs.

Subsequent to the lamination, the edges of the multi-tile module can be trimmed to eliminate excessive encapsulant (operation 1322) and the junction boxes are attached (operation 1324). Attaching a junction box can include inserting the attachment pad pre-fabricated within the junction box into the center of the gasket. In some embodiments, an automated operation can be performed to place the junction box on a predetermined location of the back cover such that the attachment pad extruding out of the junction box can fall within the through hole on the back cover. Heat can be applied locally to solder the attachment pad to the metal strip exposed by the through hole. For example, the junction box can have a removable cover to allow a solder gun to approach the attachment pad during installation of the junction boxes. In addition to attaching the junction boxes, roofing components (e.g., components that can facilitate the attachment of the multi-tile module onto a roof batten) can be attached to the back side of the multi-tile module to complete the fabrication process (operation 1326).

The foregoing descriptions of various embodiments have been presented only for purposes of illustration and description. They are not intended to be exhaustive or to limit the present system to the forms disclosed. Accordingly, many modifications and variations will be apparent to practitioners skilled in the art. Additionally, the above disclosure is not intended to limit the present system.

1. A photovoltaic roof module, comprising:
one or more photovoltaic roof tiles, wherein a respective photovoltaic roof tile comprises a plurality of photovoltaic structures positioned between a front cover and a back cover; and
a first junction box positioned on the back cover of a first photovoltaic roof tile, wherein the first junction box comprises a physical enclosure and an attachment pad extended substantially vertically out of a surface of the physical enclosure, and wherein the attachment pad is configured to electrically access, via a through hole, photovoltaic structures within the first photovoltaic roof tile.

2. The photovoltaic roof module of claim 1, wherein a respective photovoltaic structure comprises a first edge busbar positioned near an edge of a first surface and a second edge busbar positioned near an opposite edge of a second surface, and wherein the plurality of photovoltaic structures is arranged in such a way that the first edge busbar of a first photovoltaic structure overlaps the second edge busbar of an adjacent photovoltaic structure, thereby forming a cascaded string.

3. The photovoltaic roof module of claim 2, wherein the attachment pad of the first junction box is electrically coupled to a first electrode of a first polarity of the cascaded string within the first photovoltaic tile.

4. The photovoltaic roof module of claim 3, further comprising a second junction box positioned on the back cover of a second photovoltaic tile, wherein an attachment pad of the second junction box is electrically coupled to a second electrode of a second polarity of the cascaded string within the second photovoltaic tile.

5. The photovoltaic roof module of claim 4, wherein the cascaded strings within the first and second photovoltaic tiles are electrically coupled to each other in parallel by a pair of metal tabs, and wherein attachment pads of the first and second junction boxes are separately coupled to the pair of metal tabs.

6. The photovoltaic roof module of claim 1, wherein the attachment pad comprises an extension post for extending out of the first junction box, a contact pad coupled to a first end of the extension post, and a wire coupler coupled to an opposite end of the extension post.

7. The photovoltaic roof module of claim 6, wherein the contact pad is configured to be electrically and mechanically coupled to an electrode of the photovoltaic structures within the first photovoltaic roof tile.

8. The photovoltaic roof module of claim 6, wherein the wire coupler is configured to be electrically and mechanically coupled to a lead wire, wherein a portion of the lead wire extends out of the physical enclosure, and wherein the extended portion of the lead wire is inserted inside a weatherproof jacket.

9. The photovoltaic roof module of claim 6, wherein the attachment pad comprises Cu, and wherein the contact pad and the wire coupler are coated with a solder layer.

10. The photovoltaic roof module of claim 1, further comprising:
encapsulant positioned between the front and back covers; and
a gasket inserted into the through hole, thus preventing the encapsulant from overflowing into the through hole during lamination.

11-20. (canceled)
